(19) United States
(12) Patent Application Publication
(10) Pub. No.: US 2026/0090123 A1
(43) Pub. Date: Mar. 26, 2026

(54) MULTI-DIE CMOS IMAGE SENSOR INTEGRATED CIRCUIT DEVICE WITH REDUCED CAPACITANCE FLOATING DIFFUSION NODE STRUCTURE

(71) Applicant: Taiwan Semiconductor Manufacturing Company, Ltd., Hsinchu (TW)

(72) Inventors: Min-Feng Kao, Chiayi City (TW); Yen-Ting Chiang, Tainan City (TW); Jen-Cheng Liu, Hsin-Chu City (TW); Bo-Yuan Su, Hsinchu County (TW)

(21) Appl. No.: 18/893,083

(22) Filed: Sep. 23, 2024

(51) Int. Cl. H01L 27/146; H01L 25/04

(52) U.S. Cl. CPC H10F 39/809; H10F 39/014; H10F 39/80373; H10F 39/811; H10W 90/00

(57) ABSTRACT

Some embodiments relate to an integrated circuit (IC) device having an IC layer including a substrate. The substrate includes a plurality of photodetectors proximate a first side of the substrate and a plurality of floating diffusion regions among the photodetectors and proximate the first side of the substrate. The IC layer further includes a plurality of conductive structures located within a dielectric layer that includes a first side positioned on the first side of the substrate. The conductive structures include a plurality of conductive bonding structures at a second side of the dielectric layer opposite the first side of the dielectric layer. The conductive structures further include a plurality of conductive contact structures. Each of the conductive contact structures connects a corresponding one of the floating diffusion regions to a corresponding one of the conductive bonding structures.

### BACKGROUND

In some complementary metal-oxide-semiconductor (CMOS) image sensor (CIS) devices, multiple circuit dies or layers may be employed to increase pixel density. For example, a first circuit layer may include photodetectors and their associated transfer gate structures, while a second circuit layer may include selection and timing circuitry for measuring an amount of the light received at selected photodetectors. Such circuits may be incorporated within a single CIS integrated circuit (IC) device to reduce the footprint consumed by the device on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic exploded isometric view of some embodiments of a CIS multi-die (e.g., multi-layer) IC device, according to the present disclosure.

FIG. 2A illustrates a block diagram of some embodiments of a pixel cell employable in a CIS multi-layer IC device, according to the present disclosure.

FIG. 2B illustrates a schematic diagram of some embodiments of a pixel cell employable in a CIS multi-layer IC device, according to the present disclosure.

FIG. 3 illustrates a schematic/block diagram of some embodiments of a pixel cell that includes a floating diffusion node, a per-pixel circuit, and an in-pixel circuit employable in a multi-layer CIS IC device, according to the present disclosure.

FIG. 4 illustrates a block diagram of some embodiments of a multi-layer CIS IC device, according to the present disclosure.

FIGS. 5A and 5B illustrate cross-sectional and plan views, respectively, of some embodiments of a multi-layer CIS IC device employing a reduced-capacitance floating diffusion node structure, according to the present disclosure.

FIGS. 6A and 6B illustrate cross-sectional and plan views, respectively, of some embodiments of another multi-layer CIS IC device employing a reduced-capacitance floating diffusion node structure, according to the present disclosure.

FIGS. 7A and 7B illustrate cross-sectional and plan views, respectively, of some embodiments of another multi-layer CIS IC device employing a reduced-capacitance floating diffusion node structure, according to the present disclosure.

FIGS. 8A and 8B illustrate cross-sectional and plan views, respectively, of some embodiments of another multi-layer CIS IC device employing a reduced-capacitance floating diffusion node structure, according to the present disclosure.

FIGS. 9A through 9F illustrate cross-sectional side views of some embodiments of a CIS upper IC layer employing a reduced-capacitance floating diffusion node structure at various stages of manufacture, according to the present disclosure.

FIG. 10 illustrates a cross-sectional view of a preliminary state of a CIS lower IC layer prior to being employed with the CIS upper IC layer of FIG. 9F, according to the present disclosure.

FIG. 11 illustrates a cross-sectional view of the CIS lower IC layer and the CIS upper IC layer of FIGS. 5A and 5B prior to bonding, according to the present disclosure.

FIG. 12 illustrates a cross-sectional view of the CIS lower IC layer and the CIS upper IC layer of FIGS. 6A and 6B prior to bonding, according to the present disclosure.

FIG. 13 illustrates a cross-sectional view of the CIS lower IC layer and the CIS upper IC layer of FIGS. 7A and 7B prior to bonding, according to the present disclosure.

FIG. 14 illustrates a cross-sectional view of the CIS lower IC layer and the CIS upper IC layer of FIGS. 8A and 8B prior to bonding, according to the present disclosure.

FIG. 15 illustrates a methodology of forming a CIS multi-die IC device employing a reduced-capacitance floating diffusion node structure, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a complementary metal-oxide-semiconductor (CMOS) image sensor (CIS), a potential area of concern is the magnitude of capacitance associated with the electrically conductive connection with a floating diffusion node associated with one or more pixels of the sensor. More specifically, the floating diffusion node carries electrical charge associated with the amount of light impacting the photodetectors, resulting in a voltage that is taken as input to processing circuitry for the CIS. As a result, a relatively lengthy electrical connection from the floating diffusion node to the processing circuity may correspond with a relatively high capacitance value, which may result in lower pixel performance (e.g., lower conversion gain from the amount of light received to the representative voltage level).

To address these issues, the present disclosure provides some embodiments of a multi-die CIS IC device with a reduced-capacitance floating diffusion node structure. In some embodiments, a first IC layer of the IC device may include a substrate including a photodetector and a floating diffusion region proximate a first side of the substrate. The substrate may also include a conductive structure located within a dielectric layer. The dielectric layer may include a first side (e.g., frontside) positioned on a corresponding first side of the substrate. The conductive structure may include a conductive bonding structure at a second side (e.g., backside) opposite the first surface of the dielectric layer, as well as a conductive contact structure connecting the side of the substrate at the floating diffusion region to the conductive bonding structure.

In addition, in some embodiments, the conductive bonding structure of the first IC layer may be bonded with a corresponding bonding structure of a second IC layer (e.g., to electrically connect the floating diffusion region with associated processing circuitry in the second IC layer).

Accordingly, use of some embodiments may provide a CIS IC device in which the level of capacitance sometimes associated with a floating diffusion node may be reduced significantly, thus potentially increasing the conversion gain of the corresponding pixel cell. Moreover, the floating diffusion node structure noted above, embodiments of which are described in greater detail below, may also result in lower overall fabrication cost for the CIS IC device.

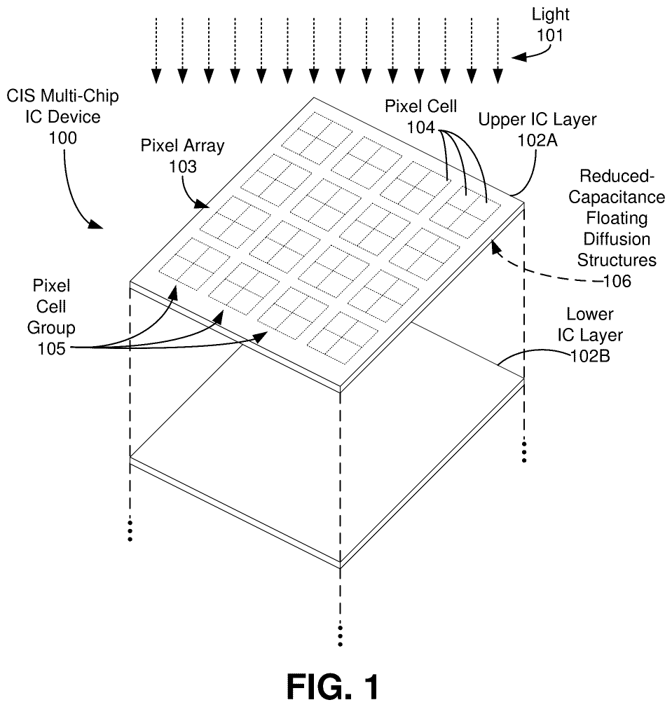

FIG. 1 illustrates a schematic exploded isometric view of some embodiments of a CIS multi-die IC device 100, according to the present disclosure. CIS multi-die IC device 100 (also referred to as CIS IC device 100 below) includes an upper (or first) IC die or layer 102A and a lower (or second) IC layer 102B that are bonded together. In some embodiments, additional lower IC layers may be included in CIS IC device 100 to provide additional functionality within a constant IC device footprint. In some embodiments, upper IC layer 102A and lower IC layer 102B are bonded at the wafer level (e.g., prior to singulation into individual ICs). In other embodiments, one or more of upper IC layer 102A and lower IC layer 102B are bonded to each other according to die-to-wafer or flip chip bonding.

In some embodiments, upper IC layer 102A includes a pixel array 103 that includes a plurality of pixel cells 104 organized as a plurality of pixel cell groups 105. Each pixel cell 104 is sensitive to light 101 impacting an upper surface (e.g., a backside surface) of upper IC layer 102A. Additionally, upper IC layer 102A may include reduced-capacitance floating diffusion structures 106, embodiments of which are described more fully below. Further, in some embodiments, upper IC layer 102A may include additional circuitry that may be incorporated with pixel cells 104. Additionally, lower IC layer 102B may include processing circuits (not shown in FIG. 1) that may be collectively employed (e.g., to generate image data representing light 101 received at pixel cells 104). In some embodiments, by organizing pixel cells 104 and other circuitry among the different IC layers 102A and 102B as described below, each such IC layer may be constructed using a fabrication process or technology node that is appropriate for the associated circuitry.

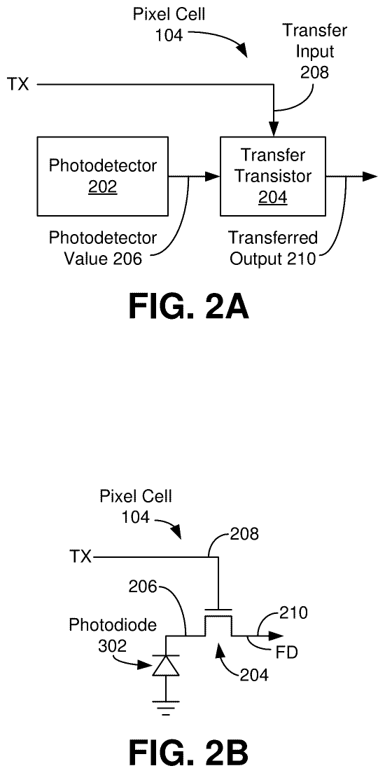

FIG. 2A illustrates a block diagram of some embodiments of pixel cell 104 employable in CIS multi-die IC device 100, according to the present disclosure. In such embodiments, pixel cell 104 may include a photodetector 202 that provides a photodetector value 206 (e.g., an amount of electrical charge) and a transfer transistor 204 that forwards the value as a transferred output 210 under the control of a transfer input 208. In some embodiments, and as described below, photodetector 202 may include a photodiode 302, such as a PIN diode or pinned photodiode (PPD). However, in other embodiments, photodetector 202 may be a phototransistor or other type of photodetector. In some embodiments, pixel cells 104 may be apportioned to detect different wavelength ranges (e.g., grouped as red, blue, and green pixels) by being associated with corresponding color filters positioned over upper IC layer 102A of FIG. 1. Also, while photodetector 202 may be sensitive to a particular visible band or range, or set of ranges, of visible light, photodetector 202 may be sensitive to non-visible light (e.g., infrared light) in other embodiments.

FIG. 2B illustrates a schematic diagram of some embodiments of pixel cell 104 employable in CIS multi-die IC device 100, according to the present disclosure. As depicted in FIG. 2B, pixel cell 104 may include a photodiode 302 with a grounded (e.g., connected to a source voltage VSS) anode and a cathode providing photodetector value 206 to a first source/drain connection of transfer transistor 204. Further, transfer transistor 204 may transfer photodetector value 206 to transferred output 210 at a second source/drain region in response to a transfer input 208 (also marked as “TX”in FIG. 2B) at a gate input of transfer transistor 204. In some embodiments, the second source/drain region of transfer transistor 204 may serve as a floating diffusion (FD) region that constitutes part of a floating diffusion node extending between upper IC layer 102A and lower IC layer 102B.

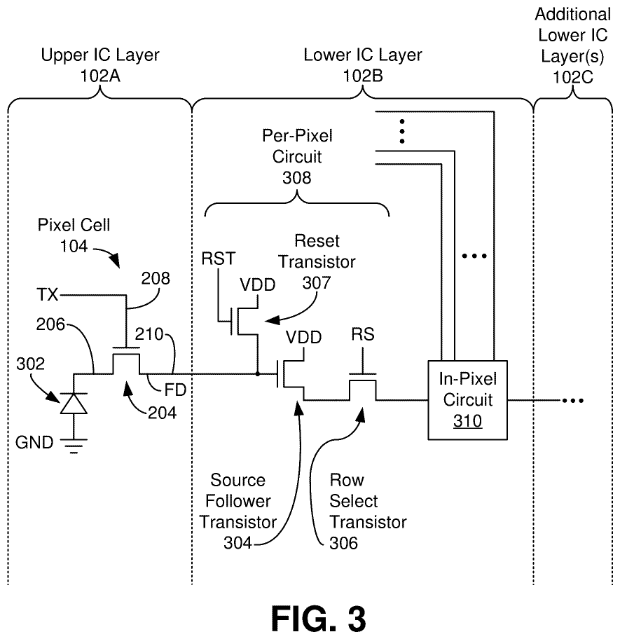

FIG. 3 illustrates embodiments in which pixel cell 104 and associated processing circuits may be organized or apportioned among three IC layers of a CIS IC device (e.g., to facilitate improved device performance and/or cost). More specifically, FIG. 3 illustrates a schematic/block diagram of some embodiments of pixel cell 104, a per-pixel circuit 308, and an in-pixel circuit 310 employable in a multiple-layer CIS IC device, according to the present disclosure. As shown, pixel cells 104, including a photodetector (e.g., photodiode 302) and transfer transistor 204, as described above, are included in upper IC layer 102A. Further, per-pixel circuit 308 and in-pixel circuit 310 are located on lower layer IC layer 102B, and additional circuitry is positioned on one or more additional lower IC layers 102C.

While a single pixel cell 104 and a single per-pixel circuit 308 are depicted in FIG. 3, at least some embodiments described herein include a plurality of pixel cells 104 (e.g., organized into pixel cell groups 105 that may include rows and columns of pixel cells 104, as depicted in FIG. 1) and a plurality of per-pixel circuits 308, where each per-pixel circuit 308 is electrically coupled to a corresponding one of pixel cells 104. As also shown in FIG. 3, each of the per-pixel circuits 308 may be coupled to in-pixel circuit 310.

In some embodiments, per-pixel circuit 308 is configured to provide a timed indication of the electrical charge (e.g., transferred output 210) transferred from photodiode 302 via transfer transistor 204 for a corresponding pixel cell 104. For example, in some embodiments, per-pixel circuit 308 may include a source follower transistor 304, a row select transistor 306, and/or a reset transistor 307. Source follower transistor 304 may be electrically coupled to transfer transistor 204 (e.g., at a gate connection of source follower transistor 304) and configured to buffer transfer transistor 204 (e.g., transferred output 210) from another circuit (e.g., within in-pixel circuit 310, such as a column bus). In some embodiments, source follower transistor 304 may be configured as an amplifier for transferred output 210. In some examples, the gate connection to source follower transistor 304 may be viewed as a floating diffusion region (marked “FD” in FIGS. 2B and 3) at which electrical charge is provided prior to being transferred to in-pixel circuit 310.

Reset transistor 307 may also be coupled to source follower transistor 304 (e.g., at a gate connection of source follower transistor 304) to reset the electrical charge being transferred from photodiode 302 by transfer transistor 204 under the control of a reset (“RST”) signal (e.g., by raising the gate connection of source follower transistor to a drain (supply) voltage VDD).

In some embodiments, row select transistor 306 may be configured to forward the electrical charge of pixel cell 104 via source follower transistor 304 to in-pixel circuit 310 in a timed manner based on a row select (“RS”) signal (e.g., driving a gate connection of row select transistor 306). Also, in some embodiments, row select transistor 306, by way of drain/source connections, may couple source follower transistor 304 to a column bus of in-pixel circuit 310.

In-pixel circuit 310, in some embodiments, may process the plurality of timed indications of electrical charge received by source follower transistor 304 (e.g., for multiple columns of pixel cells 104 on a row-by-row basis) to at least partially generate analog image data represented by the electrical charges stored in pixel cells 104. In some embodiments, in-pixel circuit 310 may generate the signals (e.g., TX, RST, and RS signals) controlling pixel cell 104 and per-pixel circuit 308, as described above. More broadly, in some embodiments, in-pixel circuit 310 may include one or more of column-level circuitry, column bus signal lines (e.g., one signal line per column), one or more bias transistors (e.g., to bias a voltage level of one or more column bus signal lines), a column controller, and a row controller.

Additional lower IC layers 102C, in some embodiments, may include any additional circuitry (e.g., one or more analog-to-digital (ADC) converters, memory, image signal processors (ISPs), communications circuitry, power circuitry, and/or the like) that may be employed as part of, or in connection with, CIS IC device 100.

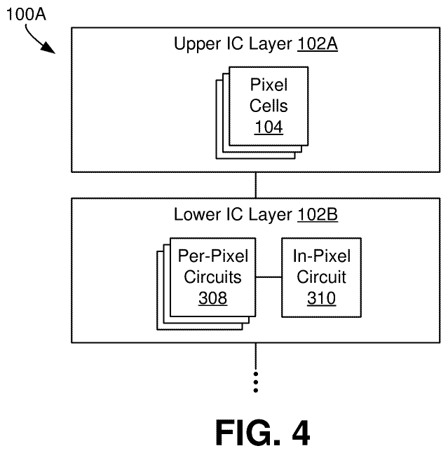

FIG. 4 illustrates a block diagram of some embodiments of a multi-layer CIS multi-die IC device 100, according to the present disclosure. For example, in FIG. 4, CIS IC device 100A includes upper IC layer 102A that includes pixel cells 104 and further includes lower IC layer 102B that includes per-pixel circuits 308 and in-pixel circuit 310 (e.g., as discussed above in connection with FIG. 3). Although not explicitly shown in FIG. 4, in some embodiments, CIS IC device 100 may also include one or more additional lower IC layers that may incorporate power circuitry (e.g., to provide, filter, and/or distribute power for CIS IC device 100), one or more memories (e.g., to store digital image data represented in pixel cells 104), and/or column ADCs (to convert the timed indications for the electrical charges of pixel cells 104 to digital image data for each column of pixel cells 104). In some embodiments, additional lower IC layers (not explicitly shown in FIG. 4) may be included in CIS IC device 100 that incorporate additional circuits, such as a phased-lock loop (PLL) (e.g., to generate timing signals for in-pixel circuit 310 and other portions of CIS IC device 100), an Inter-Integrated Circuit (I2C) (e.g., for providing communication between CIS IC device 100 and other circuits or systems), and an ISP (e.g., for processing digital image data generated from the electrical charges in pixel cells 104).

In some embodiments, the partitioning of the above-described functions among upper IC layer 102A, lower IC layer 102B, and potentially additional lower IC layers may simplify fabrication of each separate IC layer by reducing the number of different process technologies that are required to generate each separate one of the IC layers. For example, in FIG. 4, upper IC layer 102A may be fabricated using at least a specialized process directed to creating pixel cells 104 (e.g., to minimize the footprint of each pixel cell 104). Further, in some embodiments, lower IC layer 102B may be fabricated using at least a low-power technology node (e.g., to implement per-pixel circuits 308 and in-pixel circuit 310). In some embodiments, an additional lower IC layer may be implemented using at least a high-voltage (e.g., thick oxide) technology (e.g., to accommodate the relatively high-level voltages of power circuitry and/or column ADCs). In some embodiments, more than one technology node may be employed on one or more IC layers. However, employing more than one IC layer may aid in preventing the use of three or more process technology nodes on any single IC layer.

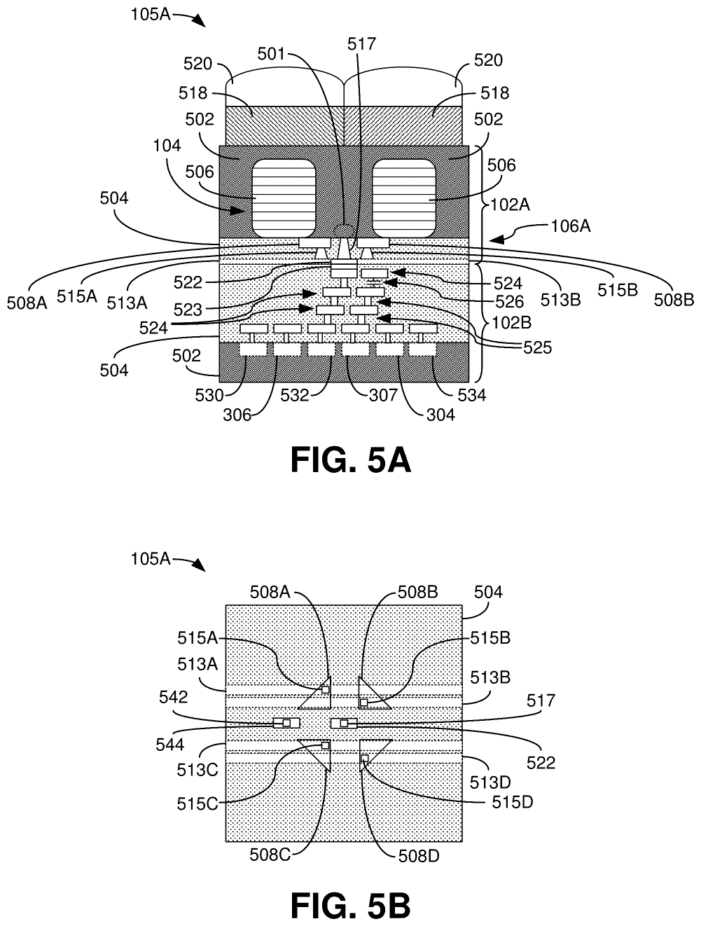

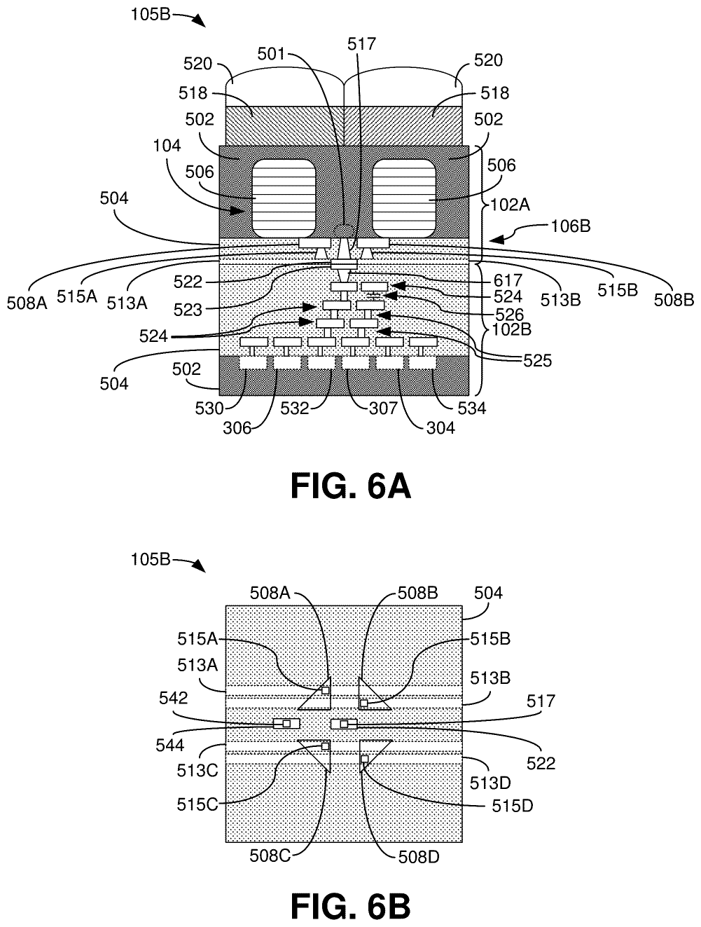

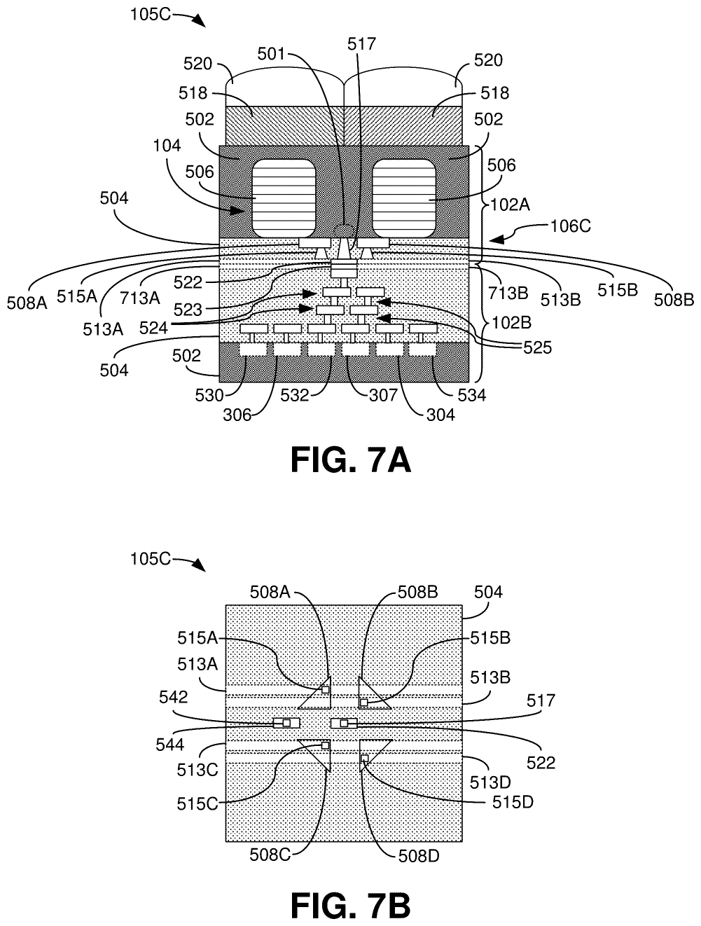

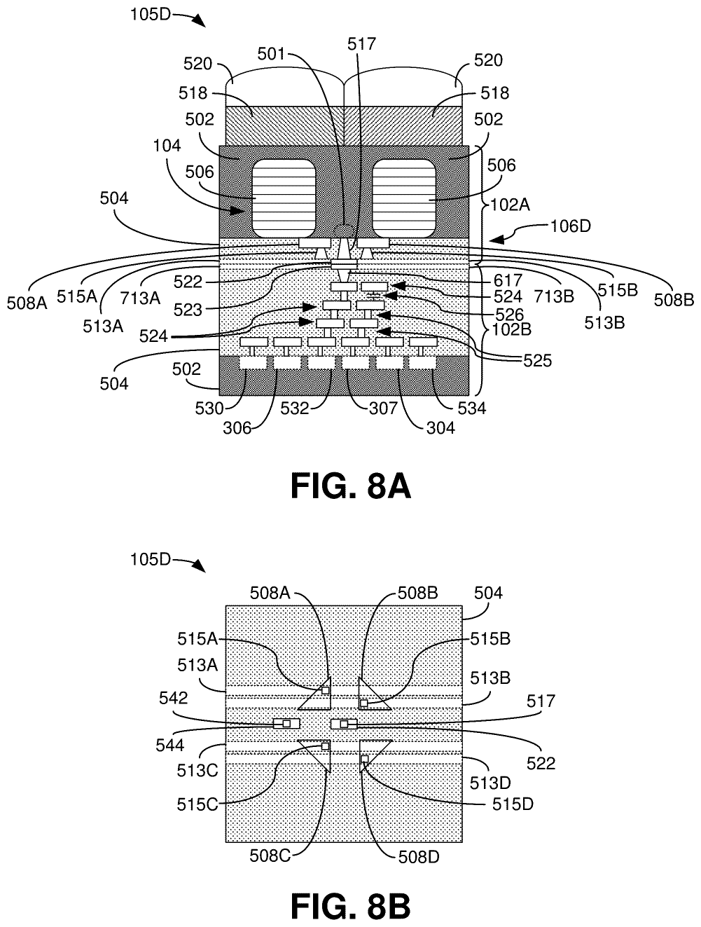

Each pair of FIGS. 5A and 5B, FIGS. 6A and 6B, FIGS. 7A and 7B, and FIGS. 8A and 8B illustrate cross-sectional and plan views, respectively, of some embodiments of a multi-layer CIS IC device employing a reduced-capacitance floating diffusion node structure, according to the present disclosure. In some embodiments, while a floating diffusion node structure may be associated with a single pixel, in the embodiments described below, the pixel cells 104 of a particular pixel cell group 105 may share a single floating diffusion region and associated node structure. More specifically, FIGS. 5A and 5B depict a pixel cell group 105A, FIGS. 6A and 6B depict a pixel cell group 105B, FIGS. 7A and 7B depict a pixel cell group 105C, and FIGS. 8A and 8B depict a pixel cell group 105D, with each pixel cell group employing a floating diffusion node structure that extends within and between upper IC layer 102A and lower IC layer 102B. Further, each of the above pairs of figures depicts a single pixel cell group 105 in upper IC layer 102A that includes a two-by-two configuration of four pixel cells 104.

Further illustrated in FIGS. 5A, 6A, 7A, and 8A are lenses (e.g., microlenses) 520 and filters 518, where one lens 520 and one associated filter 518 may be disposed over a corresponding pixel cell 104 to focus and subsequently filter light provided to pixel cell 104. In some embodiments, each pixel cell group 105 may include filters of different colors (e.g., red, green, and blue). Further, in some embodiments, one or more pixel cell groups 105 may include one red, two green, and one blue filter. However, other combinations of colors or wavelength bands may be associated with filters 518 in other embodiments.

In each of FIGS. 5A, 6A, 7A, and 8A, upper IC layer 102A may include a substrate 502 and a dielectric layer 504. In some embodiments, substrate 502 of upper IC layer 102A, as well as substrate 502 of first lower IC layer 102B, may be a semiconductor substrate that may include silicon (Si) and/or another semiconductor material. Further, in some embodiments, dielectric layer 504 of upper IC layer 102A, as well as dielectric layer 504 of lower IC layer 102B, may include one or more dielectric materials, including, but not limited to, silicon oxide (SiOₓ) (e.g., silicon dioxide (SiO₂)), silicon nitride (SiN), silicon carbide (SiC), carbon doped silicon dioxide, silicon oxynitride, borosilicate glass (BSG), phosphorus silicate glass (PSG), borophosphosilicate glass (BPSG), fluorosilicate glass (FSG), undoped silicate glass (USG), a porous dielectric material, or the like.

Regarding these same figures, substrate 502 of upper IC layer 102A may include a photosensitive region 506 for each pixel cell 104 of pixel cell group 105A, 105B, 105C, and 105D. Each photosensitive region 506 may form a corresponding photodetector (e.g., photodiode 302 of FIG. 3) with the surrounding regions of substrate 502. In some embodiments, photosensitive regions 506 are formed proximate a lower side or surface (e.g., a first or frontside surface) of substrate 502 adjacent to which dielectric layer 504 of upper IC layer 102A is disposed.

Also included in substrate 502 is a floating diffusion region 501 disposed proximate the lower (e.g., first or frontside) surface or side of substrate 502, as illustrated in FIGS. 5A, 6A, 7A, and 8A, and proximate at least one pixel cell 104. In some embodiments, as depicted in the plan views of FIGS. 5B, 6B, 7B, and 8B, floating diffusion region 501 is positioned among the individual pixel cells 104 (e.g., approximately centered within pixel cell groups 105A, 105B, 105C, and 105D). Accordingly, in some embodiments, floating diffusion region 501 is shared (e.g., on a time division basis) by pixel cells 104 of each pixel cell group 105A, 105B, 105C, and 105D. The functionality of floating diffusion region 501 is described in detail above in conjunction with FIGS. 2B and 3.

Further, in some embodiments, within dielectric layer 504, at an upper (e.g., first) side or surface proximate the first side or surface of substrate 502, a transfer gate structure 508A, 508B, 508C, and 508D (e.g., a gate oxide material with a connecting conductive structure (e.g., polycrystalline silicon, a metallic conductor, or another electrically conducting material), and possibly a spacer structure) may be proximate a photosensitive region 506 and floating diffusion region 501 to form a corresponding pixel cell 104. In addition, as depicted in the plan views of FIGS. 5B, 6B, 7B, and 8B, each transfer gate structure 508A, 508B, 508C, and 508D, may be positioned in or near a corner of a corresponding pixel cell 104 closest to a central region of the associated pixel cell group 105A, 105B, 105C, and 105D. Also, in some embodiments, each transfer gate structure 508A, 508B, 508C, and 508D may be triangular in the plan views of FIGS. 5B, 6B, 7B, and 8B (e.g., in the form of a right triangle having a right angle nearest the central region of corresponding pixel cell group 105A, 105B, 105C, and 105D). However, other locations, arrangements, and shapes for transfer gate structures 508A, 508B, 508C, and 508D are possible in other embodiments.

In some embodiments, dielectric layer 504 of upper IC layer 102A may include a plurality of conductive bonding structures at a lower (e.g., second) side or surface of dielectric layer 504 opposite substrate 502. Further, dielectric layer 504 of upper IC layer 102A may include conductive contact structures electrically connecting portions of pixel cells 104 to the conductive bonding structures of upper IC layer 102A. More specifically, in some embodiments, as illustrated in FIGS. 5A, 5B, 6A, 6B, 7A, 7B, 8A, and 8B, a conductive contact structure 517 may connect floating diffusion region 501 at the first surface of dielectric layer 504 to a conductive bonding structure 522 at the second surface of dielectric layer 504. Additionally, in some embodiments, a conductive contact structure 515A, 515B, 515C, and 515D may connect a corresponding transfer gate structure 508A, 508B, 508C, and 508D, respectively, to an associated conductive bonding structure 513A, 513B, 513C, and 513D, respectively. In some embodiments, conductive bonding structures 513A, 513B, 513C, and 513D may extend in a lateral direction parallel to each other in a plan view within pixel cell group 105A, 105B, 105C, and 105D, and may further extend into an associated row of pixel cell groups within which pixel cell group 105A, 105B, 105C, and 105D belong.

Also, as shown in FIGS. 5B, 6B, 7B, and 8B, but not explicitly depicted in FIGS. 5A, 6A, 7A, and 8A, a conductive contact structure 542 may connect the first surface of substrate 502 with a conductive bonding structure 544 at the second surface of dielectric layer 504. In some embodiments, conductive contact structure 542 and conductive bonding structure 544 constitute at least a portion of a reference voltage (e.g., ground) connection for the photodetector of each pixel cell 104 of a corresponding pixel cell group 105A, 105B, 105C, and 105D.

In some embodiments, the conductive structures disposed within dielectric layer 504 may include a metal (e.g., copper (Cu) or aluminum (Al)) or another conductive material.

Further, in some embodiments, additional dielectric structures may be disposed within upper IC layer 102A to at least partially isolate each pixel cell 104 from other pixel cells 104, and possibly from other portions of upper IC layer 102A. Such dielectric structures are not described or further discussed herein.

Lower IC layer 102B, as depicted in each of FIGS. 5A, 6A, 7A, and 8A, includes its own substrate 502 (e.g., a silicon substrate or another semiconductor substrate) and a dielectric layer 504. Within lower IC layer 102B, substrate 502 may include at least a portion one or more processing circuits. Such processing circuits, in some embodiments, may include a plurality of per-pixel circuits 308 of FIG. 3, such as source follower transistor 304, row select transistor 306, and/or a reset transistor 307). Further, in some embodiments, the processing circuits may include a polysilicon capacitor 530, a conversion gain (e.g., high/mid/low conversion gain) circuit 532, a voltage domain global shutter circuit 534, and/or other circuitry.

Within dielectric layer 504 of lower IC layer 102B, a plurality of conductive structures, or conductive element sets, may be disposed to connect various processing circuits 304, 306, 307, 530, 532, and/or 534 to conductive bonding structures 522, 513A, 513B, 513C, 513D, and/or other conductive structures of upper IC layer 102A, or to each other. In some embodiments, the conductive element sets may include one or more conductive layers 524 interspersed with one or more conductive vias 525, as illustrated in FIGS. 5A, 6A, 7A, and 8A. Further, in some embodiments, such conductive structures may include a metal (e.g., copper (Cu) or aluminum (Al)) or another electrically conductive material.

In dielectric layer 504 of lower IC layer 102B, one or more conductive bonding structures may be located at the second surface of dielectric layer 504. These conductive bonding structures may be arranged to connect the conductive structures within dielectric layer 504 of lower IC layer 102B to conductive bonding structures 522, 513A, 513B, 513C, 513D of dielectric layer 504 of upper IC layer 102A.

More specifically, in the embodiments of FIGS. 5A, 6A, 7A, and 8A, dielectric layer 504 of lower IC layer 102B includes a conductive bonding structure 523 that is bonded to conductive bonding structure 522 at the second surface of dielectric layer 504 of upper IC layer 102A. Consequently, as shown in the embodiments of FIGS. 5A and 7A, an electrically conductive connection passes from floating diffusion region 501, through conductive contact structure 517 and conductive bonding structure 522 of dielectric layer 504 of upper IC layer 102A, through conductive bonding structure 523, one or more conductive layers 524, and one or more conductive vias 525 of dielectric layer 504 of lower IC layer 102B, to conversion gain circuit 532.

Further, in FIGS. 6A and 8A, an additional conductive contact structure 617 not employed in FIGS. 5A and 5B is positioned between conductive bonding structure 523 and a top conductive layer 524 of dielectric layer 504 of lower IC layer 102B. Additional conductive contact structure 617 is thus incorporated as part of the floating diffusion node, unlike the corresponding structures of FIGS. 5A and 7A. In some embodiments, additional conductive contact structure 617 may facilitate more flexibility in metal layer routing within dielectric layer 504 of lower IC layer 102B, as well as enable the use of smaller pixel cells 104 in upper IC layer 102A.

Moreover, in some embodiments, additional conductive bonding structures, including conductive bonding structures 713A and 713B, as shown in FIGS. 7A and 8A, are provided in addition to conductive bonding structure 523 of dielectric layer 504 of lower IC layer 102B. As depicted, conductive bonding structures 713A and 713B are bonded to conductive bonding structures 513A and 513B of dielectric layer 504 of upper IC layer 102A. Moreover, additional conductive bonding structures of lower IC layer 102B (not shown in FIGS. 7A and 8A) may be bonded to conductive bonding structures 513C and 513D in other embodiments. Also, in some embodiments, conductive bonding structures 513A, 513B, 513C, and 513D of upper IC layer 102A may match a size and/or shape of corresponding conductive bonding structures 713A, 713B, and so on of upper IC layer 102B. Consequently, in some embodiments, using these additional conductive bonding structures in lower IC layer 102B may enhance the robustness of the conductive (e.g., metal) bonding regions of upper IC layer 102A and lower IC layer 102B to mitigate electromigration of the associated conductive structures, possibly resulting in increased reliability of the IC device.

Also shown in FIGS. 5A, 6A, 7A, and 8A, among the conductive structures in dielectric layer 504 of lower IC layer 102B, is a three-dimensional metal-insulator-metal (3D-MIM) capacitor 526. In other embodiments, such a capacitor may be omitted from dielectric layer 504 of lower IC layer 102B.

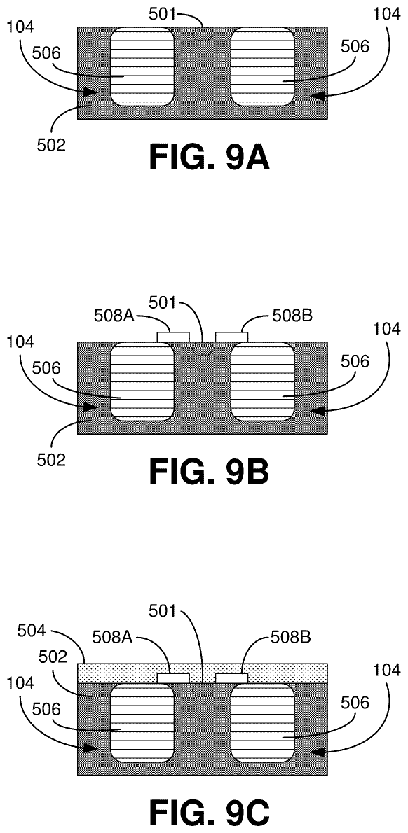

FIGS. 9A through 9F illustrate cross-sectional side views of some embodiments of a CIS upper IC layer employing a reduced-capacitance floating diffusion node structure (e.g., upper IC layer 102A of pixel cell groups 105A, 105B, 105C, and 105D of FIGS. 5A, 6A, 7A, and 8A, respectively) at various stages of manufacture, according to the present disclosure. Although FIGS. 9A through 9F are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 9A illustrates the forming (e.g., implantation or doping) of a plurality of photosensitive regions 506 formed at a first side or surface of a substrate 502. Substrate 502 may be a semiconductor substrate (e.g., a silicon (Si) substrate) that will serve as a basis for upper IC layer 102A of pixel cell group 105A, 105B, 105C, or 105D of CIS IC device 100. Each photosensitive region 506 may include a light-absorption region that, in combination with substrate 502, forms a photodetector (e.g., photodiode) that is sensitive to a light wavelength band. In some embodiments, semiconductor substrate 502 may be p-doped silicon, and photosensitive regions 506 may be portions of substrate 502 that have been implanted or doped with ions to create an n-doped region. In some embodiments, the photodiodes generated by the formation of photosensitive regions 506 may be PN photodiodes (e.g., “pinned” photodiodes) that are sensitive to photons of visible light. In addition, other doped regions, such as an n-doped floating diffusion region 501 for transfer transistors associated with transfer gate structures 508A, 508B, 508C, and 508D of each pixel cell group 105A, 105B, 105C, or 105D, may be formed proximate photosensitive regions 506.

FIG. 9B illustrates the forming (e.g., deposition and photolithography, and/or the like) of transfer gate structures 508A, 508B, 508C, and 508D coupled with the photodetector associated with each pixel cell 104 over substrate 502. In some embodiments, transfer gate structures 508A, 508B, 508C, and 508D may include polycrystalline silicon, a metal, or another electrically conductive material.

FIG. 9C illustrates the forming (e.g., deposition) of at least a portion of dielectric layer 504 over substrate 502 and transfer gate structures 508A, 508B, 508C, and 508D. In some embodiments, dielectric layer 504 may include silicon oxide (SiOₓ), such as silicon dioxide (SiO₂), and/or one or more other dielectric materials, as described above.

FIG. 9D illustrates the forming (e.g., etching or other removal of portions of dielectric layer 504) of trenches 902 through an upper side or surface of dielectric layer 504 to each of transfer gate structures 508A, 508B, 508C, and 508D, as well to floating diffusion region 501.

FIG. 9E illustrates the forming (e.g., deposition and/or photolithography) of conductive contact structures 515A, 515B, 515C, 515D, and 517 to connect with transfer gate structures 508A, 508B, 508C, and 508D, and floating diffusion region 501, respectively.

FIG. 9F illustrates the forming (e.g., by photolithography) of conductive bonding structures 513A, 513B, 513C, 513D, and 522 to connect with conductive contact structures 515A, 515B, 515C, 515D, and 517. In some embodiments, an additional layer of dielectric material may be formed (e.g., deposited) to fill the interstices between conductive bonding structures 513A, 513B, 513C, 513D, and 522. Additionally, in some embodiments, a planarization processing operation (e.g., using chemical-mechanical planarization (CMP)) may be performed on the upper side of dielectric layer 504, resulting in upper IC layer 102A.

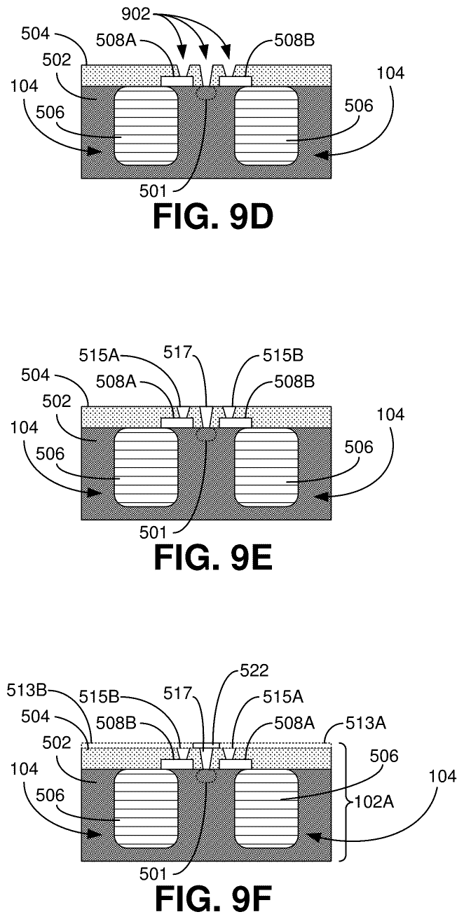

FIG. 10 illustrates a cross-sectional view of a preliminary state of lower IC layer 102B prior to being employed with upper IC layer 102A of FIG. 9F, according to the present disclosure. More specifically, FIG. 10 shows lower IC layer 102B, with substrate 502 and included processing circuits 304, 306, 307, 530, 532, and 534, in addition to associated dielectric layer 504 with a plurality of conductive layers 524 and conductive vias 525, prior to the addition of any conductive bonding structures. Accordingly, this preliminary state of lower IC layer 102B is common to each of the embodiments of FIGS. 5A, 6A, 7A, and 8A.

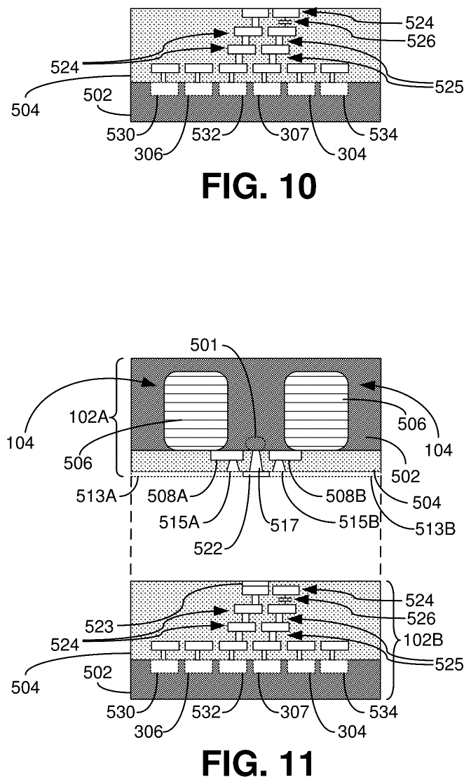

Proceeding from this preliminary state, FIGS. 11-14 depict lower IC layer 102B for each of the embodiments of FIGS. 5A, 6A, 7A, and 8A, respectively, prior to bonding with upper IC layer 102A (e.g., as shown in FIG. 9F). In each of these figures, upper IC layer 102A is depicted in a “flipped” or inverted orientation relative to its orientation in FIG. 9F to facilitate bonding with lower IC layer 102B.

For example, FIG. 11 illustrates a cross-sectional view of lower IC layer 102B and upper IC layer 102A of FIGS. 5A and 5B prior to bonding, according to the present disclosure. In some embodiments, conductive bonding structure 523 has been formed (e.g., using lithography or other means) on a top conductive (e.g., metal) layer 524 of the preliminary state of lower IC layer 102B shown in FIG. 10. The upper (e.g., second) sides or surfaces of dielectric layers 504 of upper IC layer 102A and lower IC layer 102B are then bonded together (e.g., using thermal bonding or other bonding processes) such that conductive bonding structure 522 of upper IC layer 102A and conductive bonding structure 523 of lower IC layer 102B are electrically connected. This bonding results in pixel cell group 105A of FIGS. 5A and 5B.

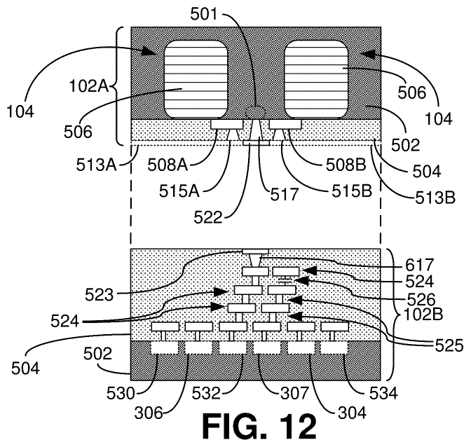

FIG. 12 illustrates a cross-sectional view of lower IC layer 102B and upper IC layer 102A of FIGS. 6A and 6B prior to bonding, according to the present disclosure. In some embodiments, conductive contact structure 617 and conductive bonding structure 523 have been formed (e.g., using lithography or other means) on a top conductive (e.g., metal) layer 524 of the preliminary state of lower IC layer 102B shown in FIG. 10. The upper (e.g., second) surfaces of dielectric layers 504 of upper IC layer 102A and lower IC layer 102B are then bonded together (e.g., using thermal bonding or other bonding processes) such that conductive bonding structure 522 of upper IC layer 102A and conductive bonding structure 523 of lower IC layer 102B are electrically connected. This bonding results in pixel cell group 105B of FIGS. 6A and 6B.

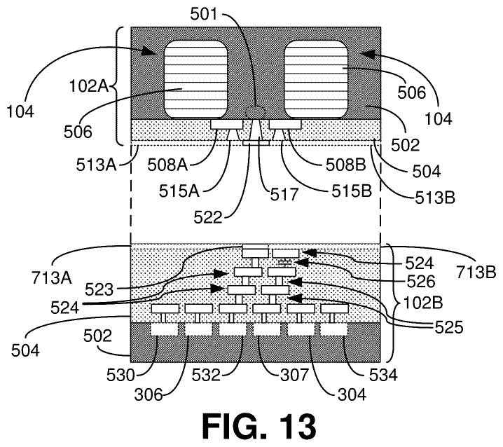

FIG. 13 illustrates a cross-sectional view of lower IC layer 102B and upper IC layer 102C of FIGS. 7A and 7B prior to bonding, according to the present disclosure. In some embodiments, conductive bonding structure 523 has been formed (e.g., using lithography or other means) on a top conductive (e.g., metal) layer 524 of the preliminary state of lower IC layer 102B shown in FIG. 10. In addition, conductive bonding structures 713A, 713B, and others corresponding to conductive bonding structures 513A, 513B, 513C, and 513D of upper IC layer 102A have been formed in dielectric layer 504. The upper (e.g., second) surfaces of dielectric layers 504 of upper IC layer 102A and lower IC layer 102B are then bonded together (e.g., using thermal bonding or other bonding processes) such that conductive bonding structure 522 of upper IC layer 102A and conductive bonding structure 523 of lower IC layer 102B are electrically connected, and such that conductive bonding structures 513A, 513B, 513C, and 513D of upper IC layer 102A and conductive bonding structures 713A, 713B, and so on of lower IC layer 102B are electrically connected. This bonding results in pixel cell group 105A of FIGS. 7A and 7B.

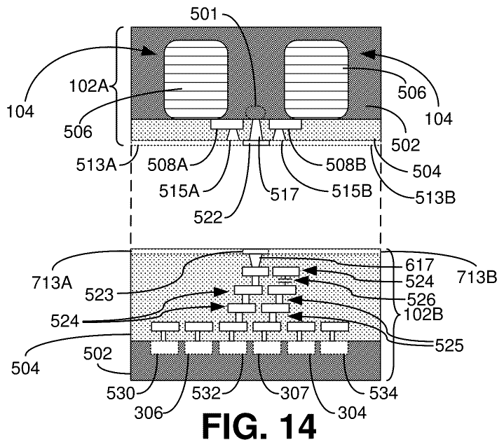

FIG. 14 illustrates a cross-sectional view of lower IC layer 102B and upper IC layer 102A of FIGS. 8A and 8B prior to bonding, according to the present disclosure. In some embodiments, conductive contact structure 617 and conductive bonding structure 523 have been formed (e.g., using lithography or other means) on a top conductive (e.g., metal) layer 524 of the preliminary state of lower IC layer 102B shown in FIG. 10. In addition, conductive bonding structures 713A, 713B, and others corresponding to conductive bonding structures 513A, 513B, 513C, and 513D of upper IC layer 102A have been formed in dielectric layer 504. The upper (e.g., second) surfaces of dielectric layers 504 of upper IC layer 102A and lower IC layer 102B are then bonded together (e.g., using thermal bonding or other bonding processes) such that conductive bonding structure 522 of upper IC layer 102A and conductive bonding structure 523 of lower IC layer 102B are electrically connected, and such that conductive bonding structures 513A, 513B, 513C, and 513D of upper IC layer 102A and conductive bonding structures 713A, 713B, and so on of lower IC layer 102B are electrically connected. This bonding results in pixel cell group 105A of FIGS. 8A and 8B.

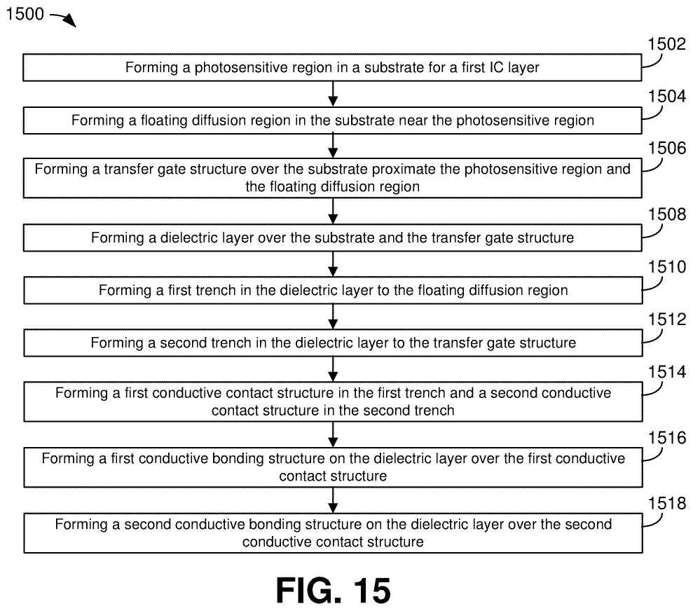

FIG. 15 illustrates a methodology 1500 of forming a CIS multi-die IC device (e.g., CIS IC device 100A, including pixel cell groups 105A, 105B, 105C, and 105D) employing a reduced-capacitance floating diffusion node structure, according to the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1502, for example, a photosensitive region (e.g., photosensitive region 506 of FIG. 9A) is formed in a substrate (e.g., substrate 502 of FIG. 9A) for a first IC layer (e.g., upper IC layer 102A of FIGS. 5A, 6A, 7A, and 8A). At Act 1504, a floating diffusion region (e.g., floating diffusion region 501 of FIG. 9A) is formed in the substrate proximate the photosensitive region. FIG. 9A illustrates a cross-sectional view of some embodiments corresponding to Acts 1502 and 1504.

At Act 1506, a transfer gate structure (e.g., transfer gate structure 508A or 508B of FIG. 9B) is formed over the substrate proximate the photosensitive region and the floating diffusion region. FIG. 9B illustrates a cross-sectional view of some embodiments corresponding to Act 1506.

At Act 1508, a dielectric layer (e.g., dielectric layer 504 of FIG. 9C) is formed over the substrate and the transfer gate structure. FIG. 9C illustrates a cross-sectional view of some embodiments corresponding to Act 1508.

At Act 1510, a first trench (e.g., trench 902 of FIG. 9D) is formed in the dielectric layer to the floating diffusion region. Also, at Act 1512, a second trench (e.g., trench 902 of FIG. 9D) is formed in the dielectric layer to the transfer gate structure. FIG. 9D illustrates a cross-sectional view of some embodiments corresponding to Acts 1510 and 1512.

At Act 1514, a first conductive contact structure (e.g., conductive contact structure 517 of FIG. 9E) is formed in the first trench and a second conductive contact structure (e.g., conductive contact structure 515A or 515B of FIG. 9E) is formed in the second trench. FIG. 9E illustrates a cross-sectional view of some embodiments corresponding to Act 1514.

At Act 1516, a first conductive bonding structure (e.g., conductive bonding structure 522 of FIG. 9F) is formed on the dielectric layer over the first conductive contact structure. At Act 1518, a second conductive bonding structure (e.g., conductive bonding structure 513A or 513B of FIG. 9F) is formed on the dielectric layer over the second conductive contact structure. FIG. 9F illustrates a cross-sectional view of some embodiments corresponding to Acts 1516 and 1518.

Some embodiments relate to a IC device. The IC device includes an IC layer that includes a substrate. The substrate includes a plurality of photodetectors proximate a first side of the substrate and a plurality of floating diffusion regions among the photodetectors and proximate the first side of the substrate. The IC layer further includes a plurality of conductive structures located within a dielectric layer that includes a first side positioned on the first side of the substrate. The conductive structures include a plurality of conductive bonding structures at a second side of the dielectric layer opposite the first side of the dielectric layer. The conductive structures further include a plurality of conductive contact structures. Each of the conductive contact structures connects a corresponding one of the floating diffusion regions to a corresponding one of the conductive bonding structures.

Some embodiments relate to another IC device. The IC device includes an IC layer that includes a substrate. The substrate includes a photodetector and a floating diffusion region proximate a first side of the substrate, and a conductive structure located within a dielectric layer. The dielectric layer includes a first side positioned on the first side of the substrate. The conductive structure includes a conductive bonding structure at a second side of the dielectric layer opposite the first side of the dielectric layer, and a conductive contact structure connecting the first side of the substrate at the floating diffusion region to the conductive bonding structure.

Some embodiments relate to a method. The method includes: forming a photosensitive region in a substrate for a first IC layer; forming a floating diffusion region in the substrate proximate the photosensitive region; forming a transfer gate structure over the substrate proximate the photosensitive region and the floating diffusion region; forming a dielectric layer over the substrate and the transfer gate structure; forming a first trench in the dielectric layer to the floating diffusion region; forming a second trench in the dielectric layer to the transfer gate structure; forming a first conductive contact structure in the first trench and a second conductive contact structure in the second trench; forming a first conductive bonding structure on the dielectric layer over the first conductive contact structure; and forming a second conductive bonding structure on the dielectric layer over the second conductive contact structure.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a first IC layer comprising:
a first substrate comprising:
a plurality of photodetectors proximate a first side of the first substrate; and
a plurality of floating diffusion regions among the plurality of photodetectors and proximate the first side of the first substrate; and
a first plurality of conductive structures located within a first dielectric layer, the first dielectric layer comprising a first side positioned on the first side of the first substrate, the first plurality of conductive structures comprising:
a plurality of first conductive bonding structures at a second side of the first dielectric layer opposite the first side of the first dielectric layer; and
a plurality of first conductive contact structures, each of the plurality of first conductive contact structures connecting a corresponding one of the plurality of floating diffusion regions to a corresponding one of the plurality of first conductive bonding structures.

2. The IC device of claim 1, wherein:
each of the plurality of photodetectors is associated with a corresponding one of a plurality of pixel cells;
the plurality of pixel cells are organized into a plurality of pixel cell groups, each of the plurality of pixel cell groups comprising four of the plurality of pixel cells in a two-by-two configuration in a plan view of the IC device; and
each of the plurality of floating diffusion regions, each of the plurality of first conductive structures, and each of the plurality of first conductive contact structures is positioned centrally among the pixel cells of a corresponding one of the plurality of pixel cell groups in the plan view of the IC device.

3. The IC device of claim 2, wherein the first plurality of conductive structures further comprises:
a plurality of transfer gate structures proximate the first side of the first dielectric layer, each of the plurality of transfer gate structures proximate a corresponding one of the plurality of photodetectors;
a plurality of second conductive bonding structures at the second side of the first dielectric layer; and
a plurality of second conductive contact structures, each of the plurality of second conductive contact structures connecting a corresponding one of the plurality of transfer gate structures to a corresponding one of the plurality of second conductive bonding structures.

4. The IC device of claim 3, wherein each of the plurality of transfer gate structures associated with one of the plurality of pixel cell groups is positioned proximate a floating diffusion region of the plurality of floating diffusion regions that is associated with the one of the plurality of pixel cell groups in the plan view of the IC device.

5. The IC device of claim 4, wherein each of the plurality of transfer gate structures associated with the one of the plurality of pixel cell groups is triangular in the plan view of the IC device.

6. The IC device of claim 5, wherein:
each of the plurality of transfer gate structures associated with the one of the plurality of pixel cell groups comprises a right angle proximate the floating diffusion region associated with the one of the plurality of pixel cell groups.

7. The IC device of claim 3, wherein each of the plurality of second conductive bonding structures associated with one of the pixel cell groups extends along a lateral direction in the plan view of the IC device.

8. The IC device of claim 7, wherein each of the plurality of second conductive bonding structures associated with one of the pixel cell groups extends along the lateral direction through one or more additional ones of the pixel cell groups in the plan view of the IC device.

9. The IC device of claim 3, further comprising a second IC layer, the second IC layer comprising:
a second substrate; and
a second plurality of conductive structures located within a second dielectric layer, the second dielectric layer comprising a first side positioned on the first side of the second substrate, the second plurality of conductive structures comprising:
a plurality of third conductive bonding structures at a second side of the second dielectric layer opposite the first side of the second dielectric layer, each of the plurality of third conductive bonding structures connected to a corresponding one of the plurality of first conductive bonding structures; and
a plurality of conductive element sets, each of the plurality of conductive element sets electrically coupling a corresponding one of the plurality of third conductive bonding structures to the second substrate.

10. The IC device of claim 9, where each of the plurality of third conductive bonding structures matches a size and a shape of the corresponding one of the plurality of first conductive bonding structures in a plan view of the IC device.

11. The IC device of claim 9, wherein each of the plurality of conductive element sets comprises a plurality of conductive layers and a plurality of conductive vias.

12. The IC device of claim 11, wherein the second plurality of conductive structures further comprises a plurality of third conductive contact structures, each of the plurality of third conductive contact structures connecting one of the plurality of third conductive bonding structures to one of the plurality of conductive layers of a corresponding one of the plurality of conductive element sets.

13. The IC device of claim 9, wherein the second plurality of conductive structures further comprises a plurality of fourth conductive bonding structures at the second side of the second dielectric layer, each of the second plurality of conductive structures connected to a corresponding one of the plurality of second conductive bonding structures.

14. The IC device of claim 13, where each of the plurality of fourth conductive bonding structures matches a size and a shape of the corresponding one of the plurality of second conductive bonding structures in a plan view of the IC device.

15. An integrated circuit (IC) device, comprising:
a first IC layer comprising:
a first substrate comprising a photodetector and a floating diffusion region proximate a first side of the first substrate; and
a first conductive structure located within a first dielectric layer, the first dielectric layer comprising a first side positioned on the first side of the first substrate, the first conductive structure comprising:
a first conductive bonding structure at a second side of the first dielectric layer opposite the first side of the first dielectric layer; and
a first conductive contact connecting the first side of the first substrate at the floating diffusion region to the first conductive bonding structure.

16. The IC device of claim 15, further comprising a second conductive structure, the second bonding structure comprising:
a transfer gate structure proximate the first side of the first dielectric layer and the photodetector;
a second conductive bonding structure at the second side of the first dielectric layer; and
a second conductive contact connecting the transfer gate structure to the second conductive bonding structure.

17. The IC device of claim 15, further comprising a second IC layer, the second IC layer comprising:
a second substrate; and
a third plurality of conductive structures located within a second dielectric layer, the second dielectric layer comprising a first side positioned on the first side of the second substrate, the third plurality of conductive structures comprising:
a third conductive bonding structure at a second side of the second dielectric layer opposite the first side of the second dielectric layer, the third conductive bonding structure connected to the first conductive bonding structure; and
a conductive element set electrically coupling the third conductive bonding structure to the second substrate.

18. A method, comprising:
forming a photosensitive region in a substrate for a first IC layer;
forming a floating diffusion region in the substrate proximate the photosensitive region;
forming a transfer gate structure over the substrate proximate the photosensitive region and the floating diffusion region;
forming a dielectric layer over the substrate and the transfer gate structure;
forming a first trench in the dielectric layer to the floating diffusion region;
forming a second trench in the dielectric layer to the transfer gate structure;
forming a first conductive contact in the first trench and a second conductive contact in the second trench;
forming a first conductive bonding structure on the dielectric layer over the first conductive contact; and
forming a second conductive bonding structure on the dielectric layer over the second conductive contact.

19. The method of claim 18, further comprising:
bonding an upper side of the first IC layer to an upper side of a second IC layer comprising a third conductive bonding structure and a fourth conductive bonding structure, wherein the first conductive bonding structure is electrically connected to the third conductive bonding structure and the second conductive bonding structure is electrically connected to the fourth conductive bonding structure.

20. The method of claim 19, wherein the bonding comprises thermal bonding.
